(19) United States
(12) Patent Application Publication
(10) Pub. No.: US 2015/0325537 A1
(43) Pub. Date: Nov. 12, 2015

(54) INTEGRATED CIRCUIT

(71) Applicant: Novatek Microelectronics Corp., Hsinchu (TW)

(72) Inventors: Kuo-Yuan Lu, Hsinchu City (TW); Wen-Ping Chou, Hsinchu County (TW); Yung-Sheng Chen, Hsinchu City (TW)

(21) Appl. No.: 14/697,631

(22) Filed: Apr. 28, 2015

Related U.S. Application Data
(60) Provisional application No. 61/985,460, filed on Apr. 28, 2014.

(30) Foreign Application Priority Data
Mar. 31, 2015 (TW) 104110499

(51) Int. Cl. H01L 23/00; H01L 23/528; H01L 23/532; H01L 23/31

(52) U.S. Cl. CPC H01L 24/05; H01L 24/13; H01L 23/3171; H01L 23/528; H01L 23/53228; H01L 23/53242; H01L 23/53209; H01L 2924/01079; H01L 2924/01029; H01L 2924/01028; H01L 2924/01046; H01L 2224/0401; H01L 2224/05124; H01L 2224/05147; H01L 2224/05016; H01L 2924/2064; H01L 2224/05666; H01L 2224/05644; H01L 2224/05647; H01L 2224/05655; H01L 2224/05664; H01L 2924/01074; H01L 2924/0132; H01L 2224/13016; H01L 2224/13147; H01L 2224/13144; H01L 2224/13155; H01L 2224/13164; H01L 2924/14

(57) ABSTRACT

An integrated circuit (IC) is provided. The IC includes a chip, a passivation layer, a first metal internal connection, a routing wire and a bonding area. The passivation layer is disposed on the chip, wherein the passivation layer has a first opening. The first metal internal connection is disposed under the passivation layer and disposed in the chip. The routing wire is disposed on the passivation layer, wherein a first end of the routing wire electrically connects to a first end of the first metal internal connection through the first opening of the passivation layer. The bonding area is disposed on the passivation layer, wherein the bonding area electrically connects to a second end of the routing wire.

### CROSS-REFERENCE TO RELATED APPLICATION

This application claims the priority benefits of U.S. provisional application Ser. No. 61/985,460, filed on Apr. 28, 2014 and Taiwan application serial no. 104110499, filed on Mar. 31, 2015. The entirety of each of the above-mentioned patent applications is hereby incorporated by reference herein and made a part of this specification.

### BACKGROUND OF THE INVENTION

1. Field of the Invention

The invention relates to a layout structure of an integrated circuit.

2. Description of Related Art

When a width (or a length) of a chip becomes longer, a metal internal connection thereof also becomes longer. For instance, a length of a metal internal connection in a high resolution source driver chip of a liquid crystal display panel may be overly long due to its long and narrow layout, resulting in a voltage drop issue inside the chip. With the metal internal connection in the chip being longer, a resistance thereof is greater to make the voltage drop issue more obvious. The voltage drop issue will slow down the operating speed. Conventional solution to said matter often adds via plugs and metal layers into the chip in a manufacturing process of the chip, so as to reduce an internal impedance of an electrical path (e.g., a system voltage VDD or a ground voltage VSS) therein. However, changing an internal circuit layout of the chip means that a plurality of wafer process masks need to be modified, and that is, expensive costs are to be spent.

### SUMMARY OF THE INVENTION

The invention is directed to an integrated circuit in which a routing wire is added on a passivation layer in order to reduce the internal impedance of the electrical path.

The integrated circuit according to embodiments of the invention includes a chip, a passivation layer, a first metal internal connection, a routing wire and a bonding area. The passivation layer is disposed on the chip, wherein the passivation layer has a first opening. The first metal internal connection is disposed under the passivation layer and disposed in the chip. The routing wire is disposed on the passivation layer, wherein a first end of the routing wire electrically connects to a first end of the first metal internal connection through the first opening of the passivation layer. The bonding area is disposed on the passivation layer, wherein the bonding area electrically connects to a second end of the routing wire.

Based on the above, in the integrated circuit according to the embodiments of the invention, the routing wire is added on the passivation layer in a packaging process after a chip process is completed, so as to reduce the internal impedance of the electrical path. Further, in comparison with changing a routing layout of the metal internal connection in the chip process, adding the routing wire in the packaging process provides greater flexibility in design while reducing overall time required by the processes.

To make the above features and advantages of the invention more comprehensible, several embodiments accompanied with drawings are described in detail as follows.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic top view illustrating a layout structure of an integrated circuit 100 according to an embodiment of the invention.

FIG. 2 is a schematic cross-sectional view illustrating the integrated circuit depicted in FIG. 1 along sectional line A-B according to an embodiment of the invention.

FIG. 3A to FIG. 3C are schematic top views illustrating the integrated circuit depicted in FIG. 1 in different steps of the manufacturing process according to an embodiment of the invention.

FIG. 4A to FIG. 4C are schematic cross-sectional views illustrating the integrated circuit along sectional line A-B according to FIG. 3A to FIG. 3C.

FIG. 5 is a schematic top view illustrating a layout structure of an integrated circuit according to another embodiment of the invention.

FIG. 6 is a schematic cross-sectional view illustrating the integrated circuit depicted in FIG. 5 along sectional line C-D according to an embodiment of the invention.

FIG. 7 is a schematic top view illustrating a layout structure of an integrated circuit according to yet another embodiment of the invention.

FIG. 8 is a schematic cross-sectional view illustrating the integrated circuit depicted in FIG. 7 along sectional line E-F according to an embodiment of the invention.

FIG. 9 is a schematic top view illustrating a layout structure of an integrated circuit according to still another embodiment of the invention.

FIG. 10 is a schematic cross-sectional view illustrating the integrated circuit depicted in FIG. 9 along sectional line G-H according to an embodiment of the invention.

FIG. 11 is a schematic top view illustrating a layout structure of an integrated circuit according to yet still another embodiment of the invention.

FIG. 12 is a schematic top view illustrating a layout structure of an integrated circuit according to another embodiment of the invention.

FIG. 13 is a schematic cross-sectional view illustrating the integrated circuit depicted in FIG. 12 along sectional line I-J according to an embodiment of the invention.

FIG. 14 is a schematic top view illustrating a layout structure of an integrated circuit according to yet another embodiment of the invention.

FIG. 15 is a schematic cross-sectional view illustrating the integrated circuit depicted in FIG. 14 along sectional line K-L according to an embodiment of the invention.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

The term “coupling/coupled” used in this specification (including claims) may refer to any direct or indirect connection means. For example, “a first device is coupled to a second device” should be interpreted as “the first device is directly connected to the second device” or “the first device is indirectly connected to the second device through other devices or connection means.” Moreover, wherever appropriate in the drawings and embodiments, elements/components/steps with the same reference numerals represent the same or similar parts. Elements/components/steps with the same reference numerals or names in different embodiments may be cross-referenced.

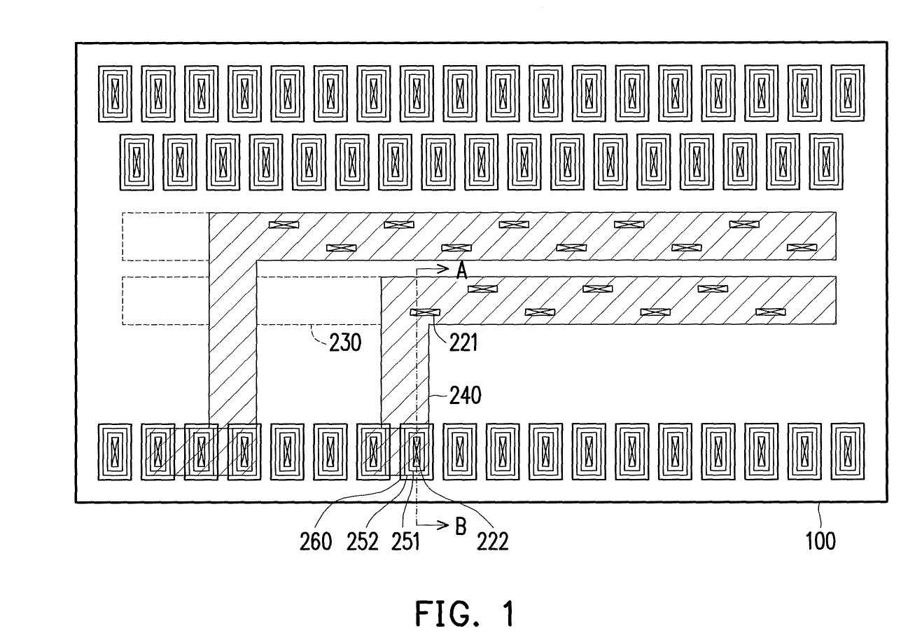

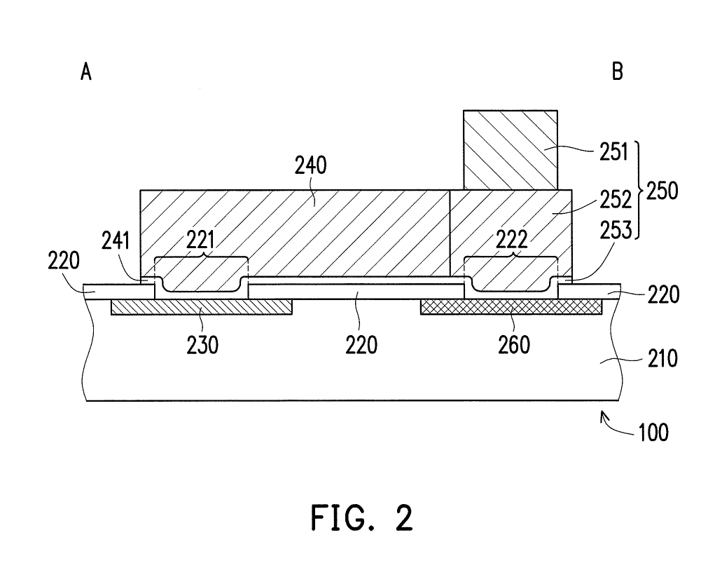

FIG. 1 is a schematic top view illustrating a layout structure of an integrated circuit 100 according to an embodiment of the invention. FIG. 2 is a schematic cross-sectional view illustrating the integrated circuit 100 depicted in FIG. 1 along sectional line A-B according to an embodiment of the invention. Referring to FIG. 1 and FIG. 2, the integrated circuit 100 includes a chip 210, a passivation layer 220, a first metal internal connection 230, a routing wire 240 and a bonding area 250. The chip 210 depicted in FIG. 2 is for illustrative purpose only. Practically, various electric elements, doped areas, metal layers, insulation layers, ploy-silicon layers, contact plugs, via plugs and/or other integrated circuit components may be provided inside, above and/or under the chip 210. After the chip process is completed, the passivation layer 220 is disposed/covers above a top metal layer of the chip 210 in order to protect the chip 210. The first metal internal connection 230 is disposed under the passivation layer 220 and disposed in the chip 210. The first metal internal connection 230 may represent any one metal layer/conductive layer in the chip 210. For instance, the first metal internal connection 230 may belong to the top metal layer of the chip 210.

After the passivation layer 220 is disposed/covers above the chip 210, the chip 210 may be transported to an assembly house for a back-end process (i.e., the packaging process). The packaging process of the integrated circuit 100 may adopt use of any method (e.g., electroplating or other methods) to dispose the routing wire 240 and the bonding area 250 on the passivation layer 220 of the chip 210. A height of the routing wire 240 may be set to fall within a range from 0.1 μm to 9 μm. In some other embodiments, the height of the routing wire 240 may be set to fall within a range from 2 μm to 5 μm. A material of the routing wire 240 may be Au, an Au compound, an Au alloy, Cu, a Cu compound, a Cu alloy, Ni, a Ni compound, a Ni alloy, Pd, a Pd compound, a Pd alloy or other low-impedance conductive materials.

In the present embodiment (but not limited thereto), the passivation layer 220 has a first opening 221 and a second opening 222. The routing wire 240 is disposed on the passivation layer 220, wherein a first end of the routing wire 240 electrically connects to a first end of the first metal internal connection 230 through the first opening 221 of the passivation layer 220. A first metal pad 260 is disposed under the passivation layer 220 and the first metal pad 260 is at least partially located under the second opening 222. A short edge length of the second opening 222 may be set to fall within a range from 4 μm to 80 μm. In some other embodiments, the short edge length of the second opening 222 may be set to fall within a range from 2 μm to 70 μm. The first metal pad 260 may be an Al pad, an Au pad or other conductive materials. For instance, a material of the first metal pad 260 may be Al, an Al compound, an Al alloy, Cu, a Cu compound, a Cu alloy or other conductive materials.

The bonding area 250 is disposed on the passivation layer 220, wherein the bonding area 250 may electrically connect to the first metal pad 260 through the second opening 222 of the passivation layer 220. The bonding area 250 electrically connects to a second end of the routing wire 240. The bonding area 250 may adopt use of any method (e.g., wiring, conductive bump or other methods) to electrically connect to a packaging pin (not illustrated) of the integrated circuit 100, so that the first metal pad 260 and/or the routing wire 240 may electrically connect to the outside of the integrated circuit 100. In some other embodiments, the routing wire 240 may electrically connect to a circuit board outside the integrated circuit 100 via the bonding area 250 by using a flip chip package method.

The bonding area 250 may be realized by using any method. For instance, the bonding area 250 depicted in FIG. 2 includes a metal bump 251, a routing layer 252 and an adhesive layer 253. The adhesive layer 253 is at least partially disposed in the second opening 222. The routing layer 252 is disposed on the passivation layer 220. The routing layer 252 is disposed on the adhesive layer 253, and the routing layer 252 electrically connects to the first metal pad 260 through the second opening 222 by the adhesive layer 253. A height of the routing layer 252 may be set to fall within a range from 0.1 μm to 9 μm. In some embodiments, the height of the routing layer 252 may be set to fall within a range from 2 μm to 5 μm. A material of the routing layer 252 may be Au, an Au compound, an Au alloy, Cu, a Cu compound, a Cu alloy, Ni, a Ni compound, a Ni alloy, Pd, a Pd compound, a Pd alloy or other conductive materials.

The adhesive layer 253 may be a TiW layer (i.e., the adhesive layer 253 being formed by stacking a Ti layer with a W layer), or the adhesive layer 253 may be realized by using a TiW alloy. In other embodiments, a material of the adhesive layer 253 may be other conductive materials (e.g., Ti, a Ti compound or other conductive materials), which is used as a connecting medium between the routing layer 252 and the first metal pad 260. The adhesive layer 253 may provide a more preferable adherence between the first metal pad 260 and the routing layer 252 in order to resist possible deformations caused by external impacts during manufacturing or bonding processes. In some other embodiments, if the favorable adhesiveness may be provided between the routing layer 252 and the first metal pad 260 based on a material combination of the routing layer 252 and the first metal pad 260, the routing layer 252 may be directly adhered with the first metal pad 260 without using the adhesive layer 253.

The routing layer 252 electrically connects to the routing wire 240. In the present embodiment, the routing layer 252 and the routing wire 240 may be disposed on the passivation layer 220 of the chip 210 in the same step (e.g., electroplating or other processing steps) of the packaging process of the integrated circuit 100. After the routing layer 252 and the routing wire 240 are disposed on the passivation layer 220 of the chip 210, a planarization process (e.g., a chemical mechanical polishing; CMP) may be utilized to planarize the routing layer 252 and the routing wire 240.

After the routing layer 252 and the routing wire 240 are planarized, the metal bump 251 may be disposed on the passivation layer 220 and the routing layer 252. The metal bump 251 electrically connects to the first metal pad 260 through the second opening 222 by the routing layer 252 and the adhesive layer 253. A material of the metal bump 251 may be Au, an Au compound, an Au alloy, Cu, a Cu compound, a Cu alloy, Ni, a Ni compound, a Ni alloy, Pd, a Pd compound, a Pd alloy or other conductive materials. Alternatively, in other embodiments, the metal bump 251 may be a metal bump of multilayer structure composed of parts selected from aforesaid materials.

A height of the metal bump 251 may be set to fall within a range from 3 μm to 18 μm. In some other embodiments, the height of the metal bump 251 may be set to fall within a range from 5 μm to 15 μm. A height difference between the metal bump 251 and the routing layer 252 (or a height difference between the metal bump 251 and the routing wire 240) may be determined based on design requirements or processing requirements. For instance, in some embodiments, the height difference between the routing layer 252 (or the routing wire 240) and the metal bump 251 may be greater than 5 μm.

A surface roughness of the metal bump 251 may be set to fall within a range from 0.05 μm to 2 μm. In some other embodiments, the surface roughness of the metal bump 251 may be set to fall within a range from 0.8 μm to 1.7 μm. A hardness of the metal bump 251 may be set to fall within a range from 25 to 120 Hv. In some other embodiments, the hardness of the metal bump 251 may be set to fall within a range from 50 to 110 Hv.

An area ratio of the second opening 222 to the metal bump 251 may be set to fall within a range from 0% to 90% in a vertical direction of the chip 210. In some other embodiments, the area ratio of the second opening 222 to the metal bump 251 may be set to fall within a range from 5% to 33%.

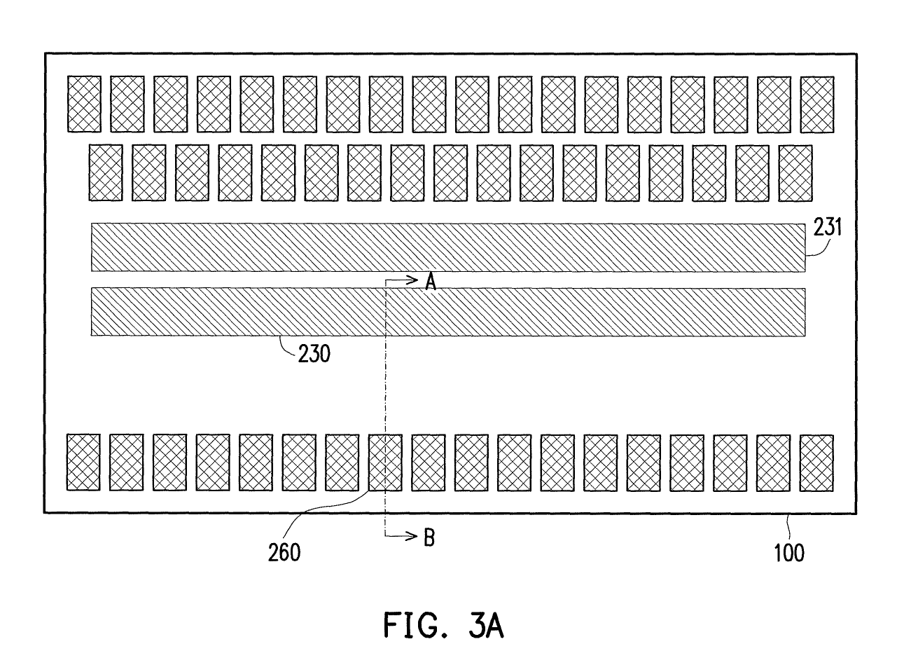

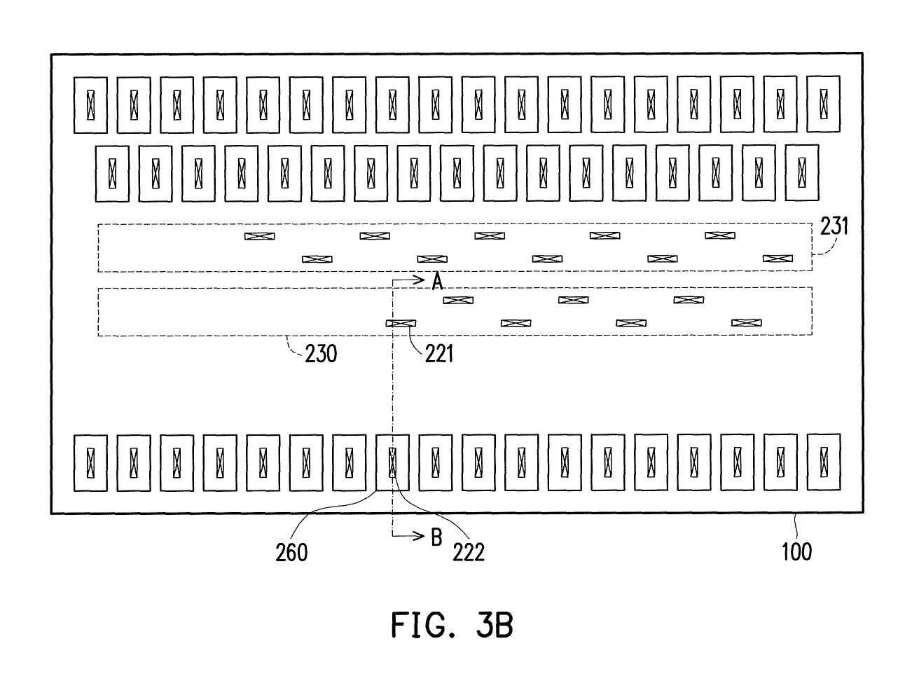

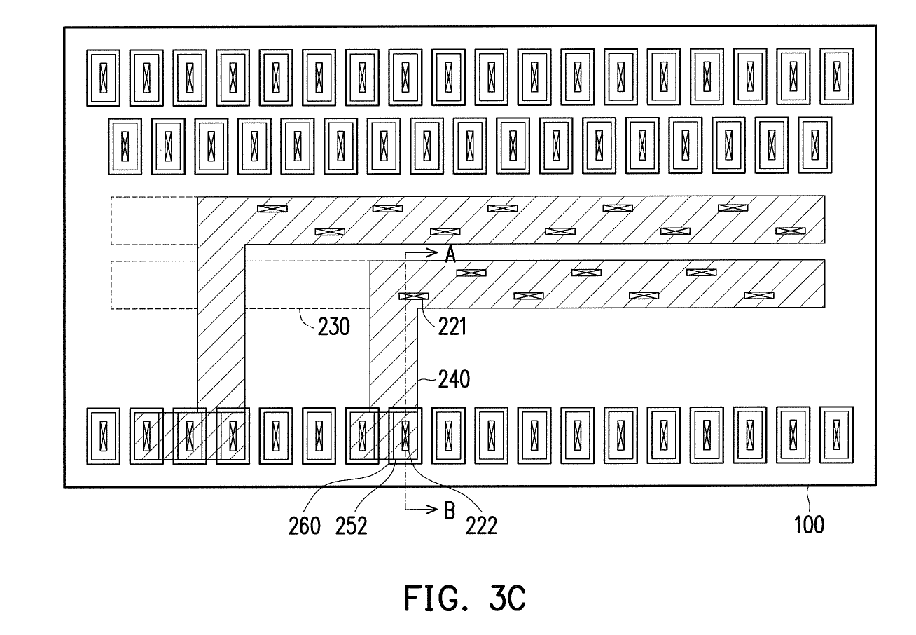

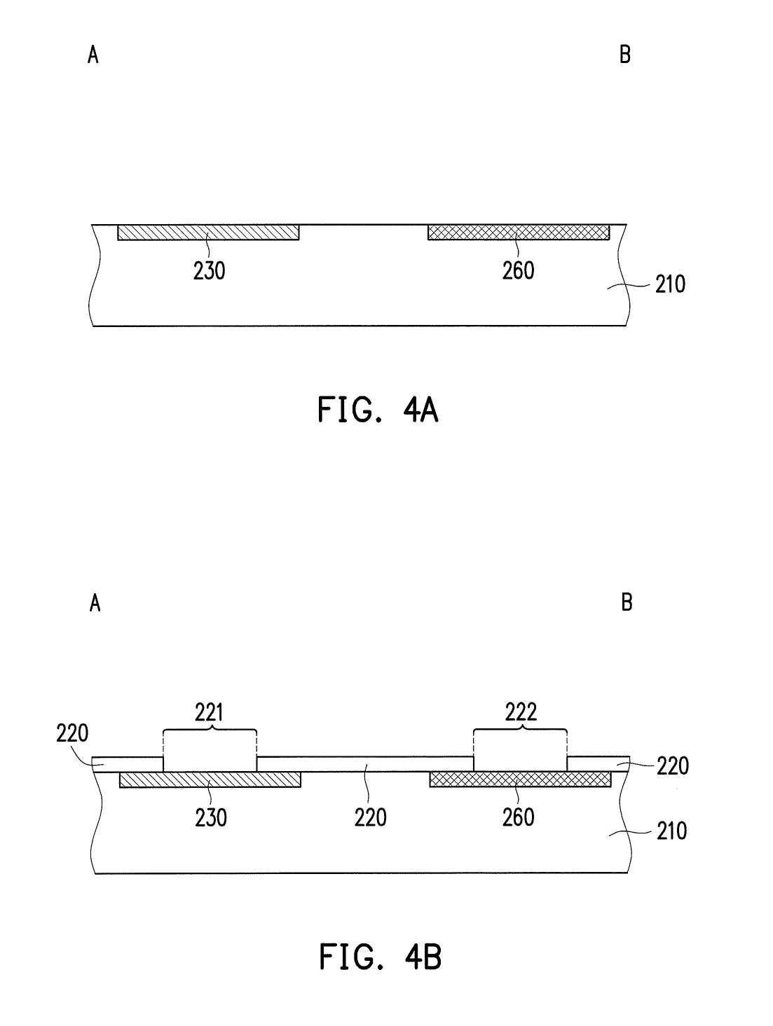

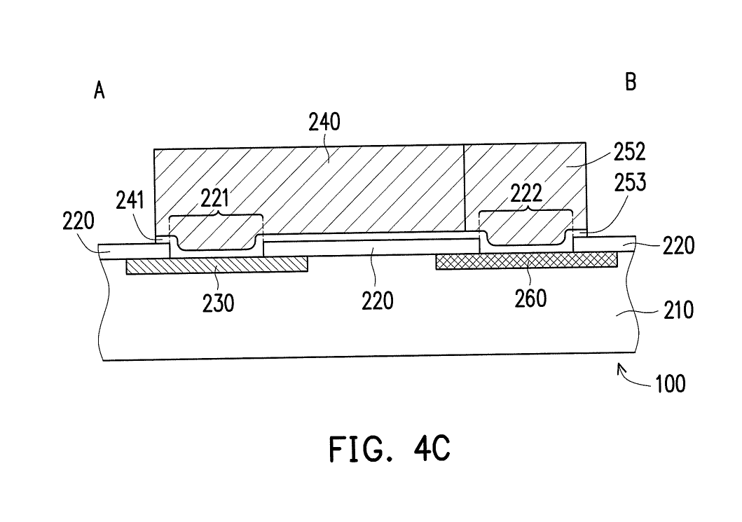

A manufacturing method of the integrated circuit 100 will be described as follows. FIG. 3A to FIG. 3C are schematic top views illustrating the integrated circuit 100 depicted in FIG. 1 in different steps of the manufacturing process according to an embodiment of the invention. FIG. 4A to FIG. 4C are schematic cross-sectional views illustrating the integrated circuit 100 along sectional line A-B according to FIG. 3A to FIG. 3C.

The chip 210 depicted in FIG. 3A and FIG. 4A is merely for illustrative purpose. Practically, various electric elements, doped areas, metal layers, insulation layers, ploy-silicon layers, contact plugs, via plugs and/or other integrated circuit components may be provided inside, above and/or under the chip 210. For example, the top metal layer of the chip 210 includes the metal internal connection 230, a metal internal connection 231 and the first metal pad 260.

Referring to FIG. 3B and FIG. 4B, after the chip process is completed, the passivation layer 220 is disposed/covers above the top metal layer (the metal internal connection 230 and the first metal pad 260) of the chip 210 in order to protect the chip 210. The passivation layer 220 at least has the first opening 221 and the second opening 222. The first opening 221 may expose a part of the first metal internal connection 230. The second opening 222 may expose a part of the first metal pad 260. After the passivation layer 220 is disposed on the chip 210, the planarization process (e.g., the chemical mechanical polishing, etc.) may be performed thereto, so as to improve a flatness of the passivation layer 220.

Referring to FIG. 3C and FIG. 4C, after the passivation layer 220 is disposed/covers above the chip 210, the back-end process (i.e., the packaging process) may be performed on the chip 210 in the assembly house. The packaging process of the integrated circuit 100 may adopt any method (e.g., electroplating or other methods) to dispose the routing wire 240, an adhesive layer 241, the adhesive layer 253 and the routing layer 252 on the passivation layer 220 of the chip 210. The adhesive layer 241 is at least partially disposed in the first opening 221. The routing wire 240 is disposed on the adhesive layer 241, and the routing wire 240 electrically connects to the first metal internal connection 230 through the first opening 221 by the adhesive layer 241. The adhesive layer 253 is at least partially disposed in the second opening 222. The routing layer 252 is disposed on the adhesive layer 253, and the routing layer 252 electrically connects to the first metal pad 260 through the second opening 222 by the adhesive layer 253. The routing layer 252 and the routing wire 240 may be disposed on the passivation layer 220 of the chip 210 simultaneously in the same step (e.g., electroplating or other processing steps) of the packaging process of the integrated circuit 100. After the routing layer 252 and the routing wire 240 are disposed on the passivation layer 220 of the chip 210, the planarization process (e.g., the chemical mechanical polishing) may be utilized to planarize the routing layer 252 and the routing wire 240.

After the routing layer 252 and the routing wire 240 are planarized, the metal bump 251 is then disposed on the passivation layer 220 and the routing layer 252, as shown in FIG. 1 and FIG. 2. The metal bump 251 may electrically connect to the first metal pad 260 through the second opening 222 by the routing layer 252 and the adhesive layer 253. The metal bump 251 may also electrically connect to the first metal internal connection 230 through the first opening 221 by the routing layer 252, the routing wire 240 and the adhesive layer 241.

A surface roughness of the metal bump 251 may be controlled by a process of disposing the metal bump. The surface roughness of the metal bump 251 is 0.05 μm to 2 μm, and more preferably, 0.8 μm to 1.7 μm. The surface roughness being too large (e.g., ≧2 μm) may result in poor contact during the bonding process of the metal bump 251. The surface roughness being too mall (e.g., ≦0.05 μm) may affect a capability of the metal bump 251 for trapping conductive particles.

A hardness range suitable for the metal bump 251 is 25 to 120 Hv, and more preferably, 50 to 110 Hv. When the integrated circuit 100 is bonded to the circuit board (e.g., a COG panel), if the hardness of the metal bump 251 is too high (e.g., >110 Hv), it is possible that a reliability thereof may be affected since a cracking may occur on the passivation layer 220 at edges of the metal bump 251. If the hardness of the metal bump 251 is too low (e.g., <50 Hv), when the integrated circuit 100 is bonded to the circuit board (e.g., the COG panel), it is possible that a poor conductive condition may occur because the conductive particles cannot be easily crashed by the metal bump 251.

In view of the above, in the integrated circuit 100 according to the present embodiment, the routing wire 240 is added on the passivation layer 220 in the packaging process after the chip process is completed. Because the routing wire 240 has a low resistance, electrical energy (e.g., a data signal, a control signal, loss of the system voltage VDD or the ground voltage VSS) in the electrical path may be reduced to prevent the operating speed from slowing down due to the voltage drop issue. Further, in comparison with changing a routing layout of the metal internal connection in the chip process, adding the routing wire in the packaging process provides greater flexibility in design while reducing overall time required by the processes. The integrated circuit 100 of the present embodiment may be applied in a Chip On Glass (COG) product, a Chip On Film (COF) product, a Chip On Board (COB) product or other IC products.

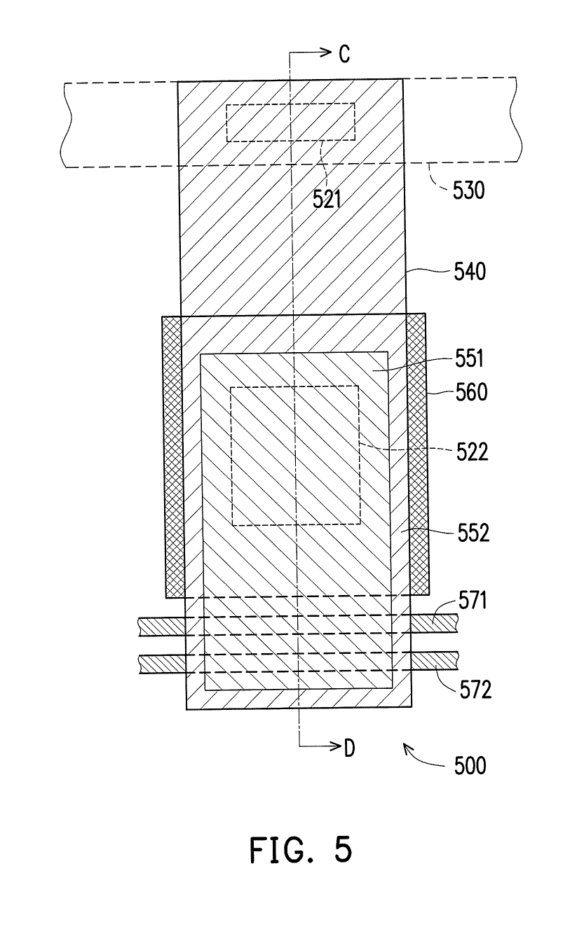

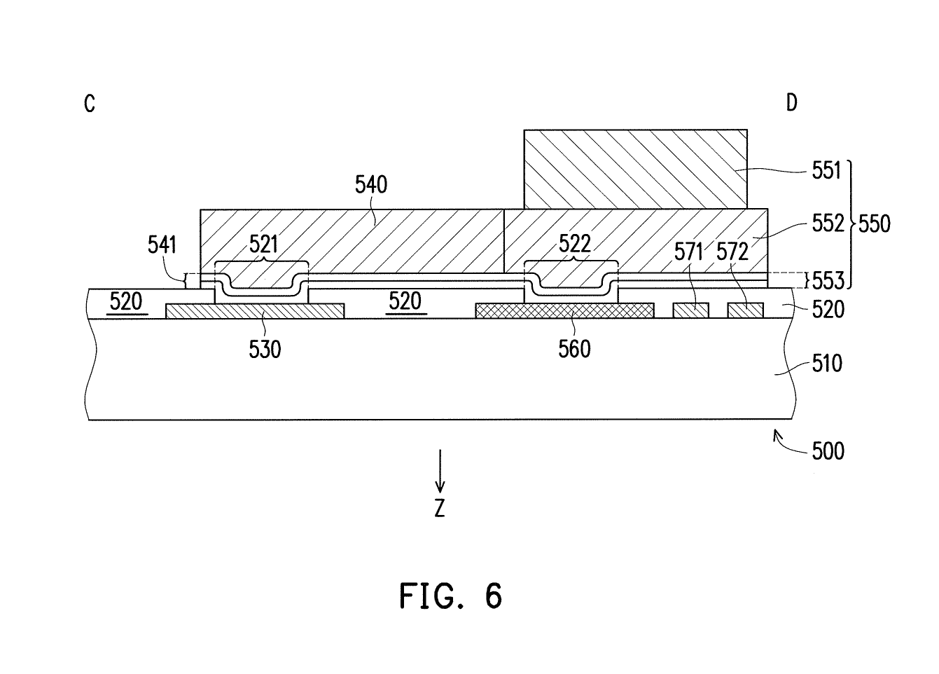

FIG. 5 is a schematic top view illustrating a layout structure of an integrated circuit 500 according to another embodiment of the invention. FIG. 6 is a schematic cross-sectional view illustrating the integrated circuit 500 depicted in FIG. 5 along sectional line C-D according to an embodiment of the invention. Referring to FIG. 5 and FIG. 6, the integrated circuit 500 includes a chip 510, a passivation layer 520, a first metal internal connection 530, a routing wire 540, an adhesive layer 541, a bonding area 550 and a first metal pad 560. The bonding area 550 includes a metal bump 551, a routing layer 552 and an adhesive layer 553. The chip 510, the passivation layer 520, the first metal internal connection 530, the routing wire 540, the adhesive layer 541, the bonding area 550, the metal bump 551, the routing layer 552, the adhesive layer 553 and the first metal pad 560 as illustrated in FIG. 5 and FIG. 6 may refer to related descriptions for the chip 210, the passivation layer 220, the first metal internal connection 230, the routing wire 240, the adhesive layer 241, the bonding area 250, the metal bump 251, the routing layer 252, the adhesive layer 253 and the first metal pad 260 as illustrated in FIG. 1, FIG. 2, FIG. 3A to FIG. 3C and FIG. 4A to FIG. 4C, which are not repeated hereinafter.

In the present embodiment (but not limited thereto), the passivation layer 520 has a first opening 521 and a second opening 522. The first opening 521 and the second opening 522 as illustrated in FIG. 5 and FIG. 6 may refer to related descriptions for the first opening 221 and the second opening 222 as illustrated in FIG. 1, FIG. 2, FIG. 3A to FIG. 3C and FIG. 4A to FIG. 4C. A first end of the routing wire 540 electrically connects to a first end of the first metal internal connection 530 through the first opening 541 of the passivation layer 520 by the adhesive layer 541. The routing layer 552 electrically connects to the first metal pad 560 through the second opening 522 of the passivation layer 520 by the adhesive layer 553.

In the embodiment shown by FIG. 5 and FIG. 6, the integrated circuit 500 further includes second metal internal connections 571 and 572. The second metal internal connections 571 and 572 may be a power line, a ground line, a data line, a control line, a floating metal or other wires in the chip 510. The second metal internal connections 571 and 572 are disposed under the passivation layer 520 and disposed in the chip 510. The second metal internal connections 571 and 572 are located at a first side of the first metal pad 560 without contacting the first metal pad 560. The metal bump 551 is at least partially overlapped with the first metal pad 560 and at least partially overlapped with the second metal internal connections 571 and 572 in a vertical direction of the chip 510 (e.g., a vertical direction Z depicted in FIG. 6). The description above may refer to a Bump On Active (BOA) design. The passivation layer 520 is disposed between the metal bump 551 and the metal internal connections 571 and 572. For instance (but not limited thereto), a width of each of the metal internal connections 571 and 572 may be 0.1 μm to 40 μm. A distance from an edge of the metal internal connection 571 to an edge of the metal pad 560 may be greater than 0.1 μm.

In view of the above, in the integrated circuit 500 according to the present embodiment, by reducing the second hole 522 (i.e., effectively reducing an area of the metal pad 560), the metal internal connections 571 and 572 may be placed under the metal bump 551, so as to increase a routing area of the top metal layer in order to facilitate the metal internal connections in routing design.

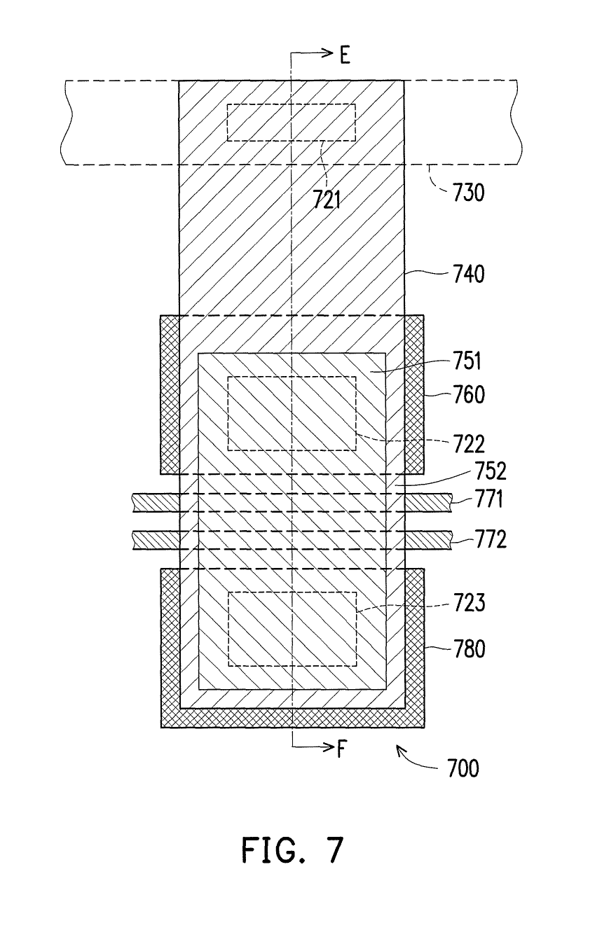

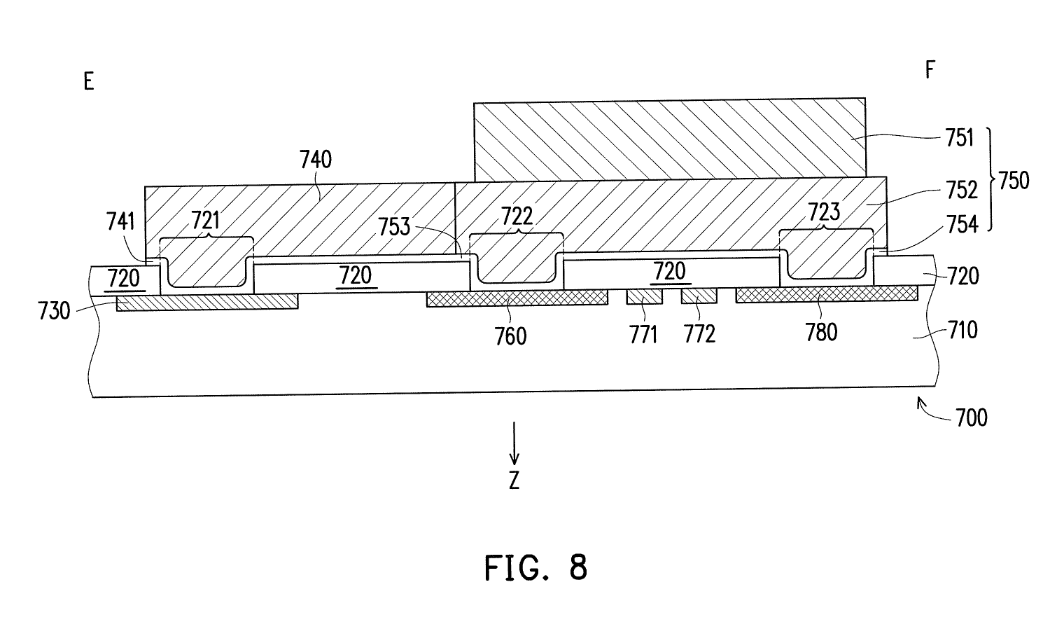

FIG. 7 is a schematic top view illustrating a layout structure of an integrated circuit 700 according to yet another embodiment of the invention. FIG. 8 is a schematic cross-sectional view illustrating the integrated circuit 700 depicted in FIG. 7 along sectional line E-F according to an embodiment of the invention. Referring to FIG. 7 and FIG. 8, the integrated circuit 700 includes a chip 710, a passivation layer 720, a first metal internal connection 730, a routing wire 740, an adhesive layer 741, a bonding area 750 and a first metal pad 760. The bonding area 750 includes a metal bump 751, a routing layer 752 and an adhesive layer 753. The chip 710, the passivation layer 720, the first metal internal connection 730, the routing wire 740, the adhesive layer 741, the bonding area 750, the metal bump 751, the routing layer 752, the adhesive layer 753 and the first metal pad 760 as illustrated in FIG. 7 and FIG. 8 may refer to related descriptions for the chip 210, the passivation layer 220, the first metal internal connection 230, the routing wire 240, the adhesive layer 241, the bonding area 250, the metal bump 251, the routing layer 252, the adhesive layer 253 and the first metal pad 260 as illustrated in FIG. 1, FIG. 2, FIG. 3A to FIG. 3C and FIG. 4A to FIG. 4C, which are not repeated hereinafter.

In the present embodiment (but not limited thereto), the passivation layer 720 has a first opening 721 and a second opening 722. The first opening 721 and the second opening 722 as illustrated in FIG. 7 and FIG. 8 may refer to related descriptions for the first opening 221 and the second opening 222 as illustrated in FIG. 1, FIG. 2, FIG. 3A to FIG. 3C and FIG. 4A to FIG. 4C. A first end of the routing wire 740 electrically connects to a first end of the first metal internal connection 730 through the first opening 721 of the passivation layer 720 by the adhesive layer 741. The routing layer 752 electrically connects to the first metal pad 760 through the second opening 722 of the passivation layer 720 by the adhesive layer 753.

In the embodiment shown by FIG. 7 and FIG. 8, the integrated circuit 700 further includes a second metal internal connection 771, a second metal internal connection 772 and a second metal pad 780, and the bonding area 750 further includes an adhesive layer 754. The metal internal connections 771 and 772 as illustrated in FIG. 7 and FIG. 8 may refer to related descriptions for the metal internal connections 571 and 572 as illustrated in FIG. 5 and FIG. 6. The second metal pad 780 may refer to related descriptions for the first metal pad 260 as illustrated in FIG. 1, FIG. 2, FIG. 3 to FIG. 3C and FIG. 4A to FIG. 4C. The second metal pad 780 is disposed under the passivation layer 720 and located at a first side of the first metal pad 760. The second metal internal connections 771 and 772 are disposed between the first metal pad 760 and the second metal pad 780. The metal bump 751 is at least partially overlapped with the second metal pad 780 in a vertical direction of the chip 710 (e.g., a vertical direction Z depicted in FIG. 8). The passivation layer 720 further includes a third opening 723. The second metal pad 780 is at least partially located under the third opening 723, and the metal bump 751 electrically connects to the second metal pad 780 through the third opening 723 of the passivation layer 720 by the adhesive layer 754.

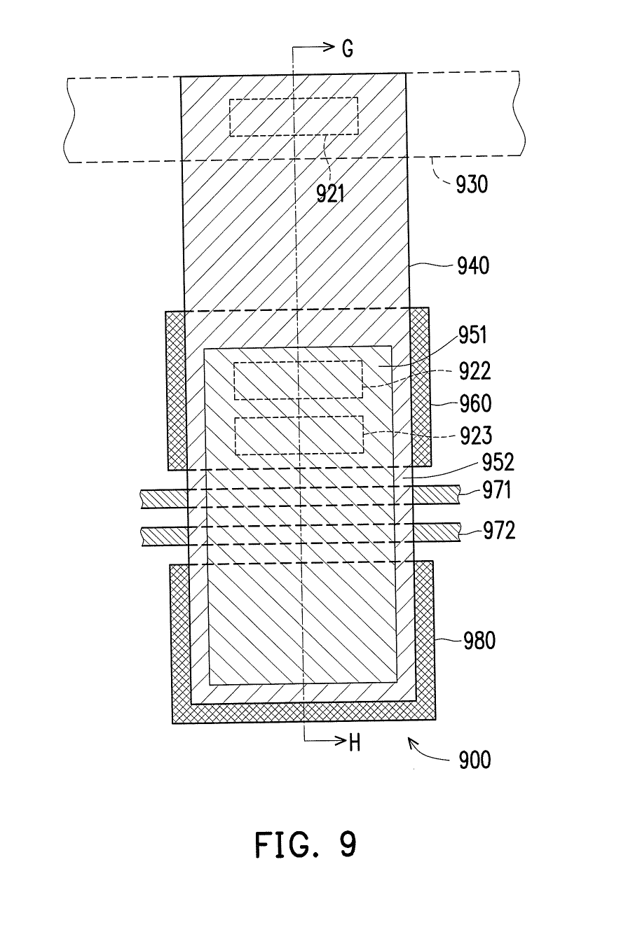

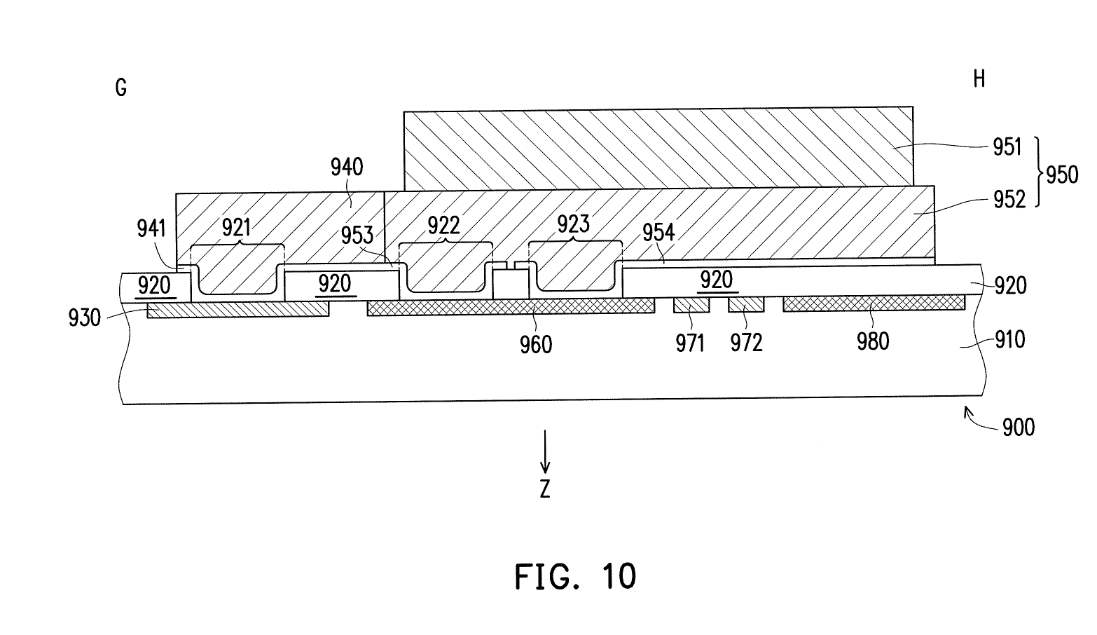

FIG. 9 is a schematic top view illustrating a layout structure of an integrated circuit 900 according to still another embodiment of the invention. FIG. 10 is a schematic cross-sectional view illustrating the integrated circuit 900 depicted in FIG. 9 along sectional line G-H according to an embodiment of the invention. Referring to FIG. 9 and FIG. 10, the integrated circuit 900 includes a chip 910, a passivation layer 920, a first metal internal connection 930, a routing wire 940, an adhesive layer 941, a bonding area 950, a metal internal connection 971, a metal internal connection 972, a first metal pad 960 and a second metal pad 980. The bonding area 950 includes a metal bump 951, a routing layer 952, an adhesive layer 953 and an adhesive layer 954. The chip 910, the passivation layer 920, the first metal internal connection 930, the routing wire 940, the adhesive layer 941, the bonding area 950, the metal bump 951, the routing layer 952, the adhesive layer 953, the adhesive layer 954 and the first metal pad 960 as illustrated in FIG. 9 and FIG. 10 may refer to related descriptions for the chip 210, the passivation layer 220, the first metal internal connection 230, the routing wire 240, the adhesive layer 241, the bonding area 250, the metal bump 251, the routing layer 252, the adhesive layer 253 and the first metal pad 260 as illustrated in FIG. 1, FIG. 2, FIG. 3A to FIG. 3C and FIG. 4A to FIG. 4C, which are not repeated hereinafter. The metal internal connection 971, the metal internal connection 972, the first metal pad 960, the second metal pad 980, the metal bump 951 and the routing layer 952 as illustrated in FIG. 9 and FIG. 10 may refer to related descriptions for the metal internal connection 771, the metal internal connection 772, the first metal pad 760, the second metal pad 780, the metal bump 751 and the routing slayer 752 as illustrated in FIG. 7 and FIG. 8.

In the embodiment shown by FIG. 9 and FIG. 10 (but not limited thereto), the passivation layer 920 has a first opening 921, a second opening 922 and a third opening 923. The first opening 921, the second opening 922 and the third opening 923 as illustrated in FIG. 9 and FIG. 10 may refer to related descriptions for the first opening 221 and the second opening 222 as illustrated in FIG. 1, FIG. 2, FIG. 3A to FIG. 3C and FIG. 4A to FIG. AC. A first end of the routing wire 940 electrically connects to a first end of the first metal internal connection 930 through the first opening 921 of the passivation layer 920 by the adhesive layer 941. The routing layer 952 electrically connects to the first metal pad 960 through the second opening 922 of the passivation layer 920 by the adhesive layer 953. The routing layer 952 also electrically connects to the first metal pad 960 through the third opening 923 of the passivation layer 920 by the adhesive layer 954. No opening is provided on the passivation layer 920 between the routing layer 952 and the second metal pad 980.

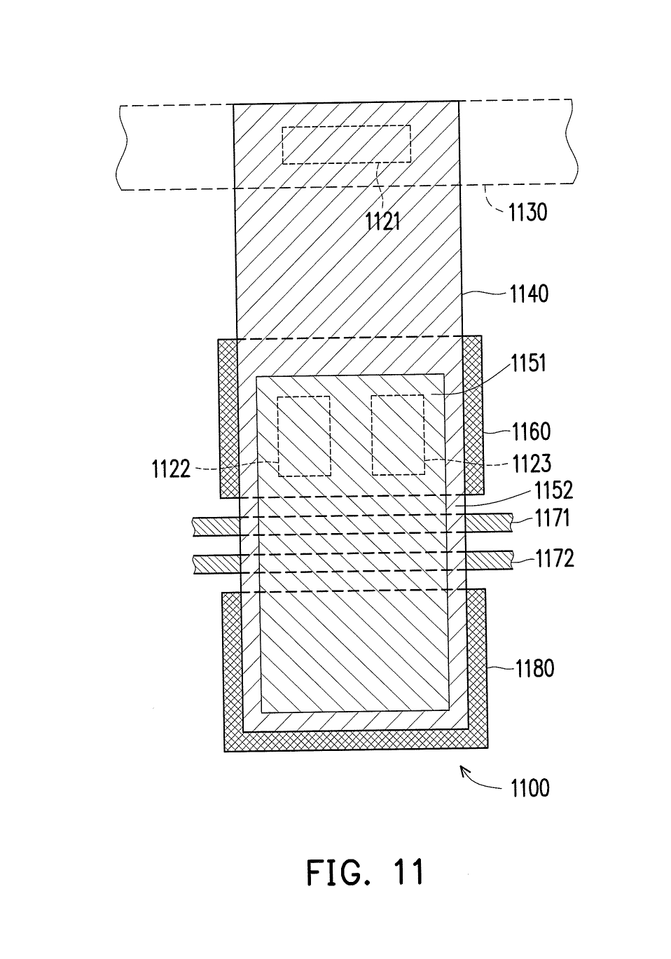

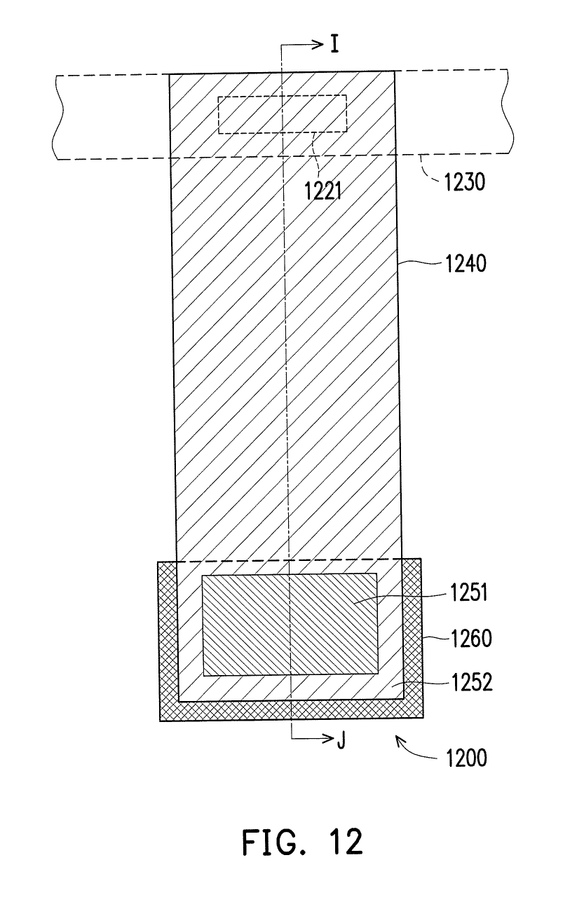

FIG. 11 is a schematic top view illustrating a layout structure of an integrated circuit 1100 according to yet still another embodiment of the invention. The integrated circuit 1100 includes a first metal internal connection 1130, a routing wire 1140, a metal bump 1151, a routing layer 1152, a first metal pad 1160, a metal internal connection 1171, a metal internal connection 1172 and a second metal pad 1180. The integrated circuit 1100 illustrated in FIG. 11 may be inferred with reference to related descriptions for the integrated circuit 900 as illustrated in FIG. 9 and FIG. 10, which are not repeated hereinafter.

In the embodiment shown by FIG. 11 (but not limited thereto), the passivation layer has a first opening 1121, a second opening 1122 and a third opening 1123. The first opening 1121, the second opening 1122 and the third opening 1123 as illustrated in FIG. 11 may refer to related descriptions for the first opening 221 and the second opening 222 as illustrated in FIG. 1, FIG. 2, FIG. 3A to FIG. 3C and FIG. 4A to FIG. AC. A first end of the routing wire 1140 electrically connects to a first end of the first metal internal connection 1130 through the first opening 1121 of the passivation layer. The routing layer 1152 electrically connects to the first metal pad 1160 through the second opening 1122 and the third opening 1123 of the passivation layer. No opening is provided on the passivation layer between the routing layer 1152 and the second metal pad 1180.

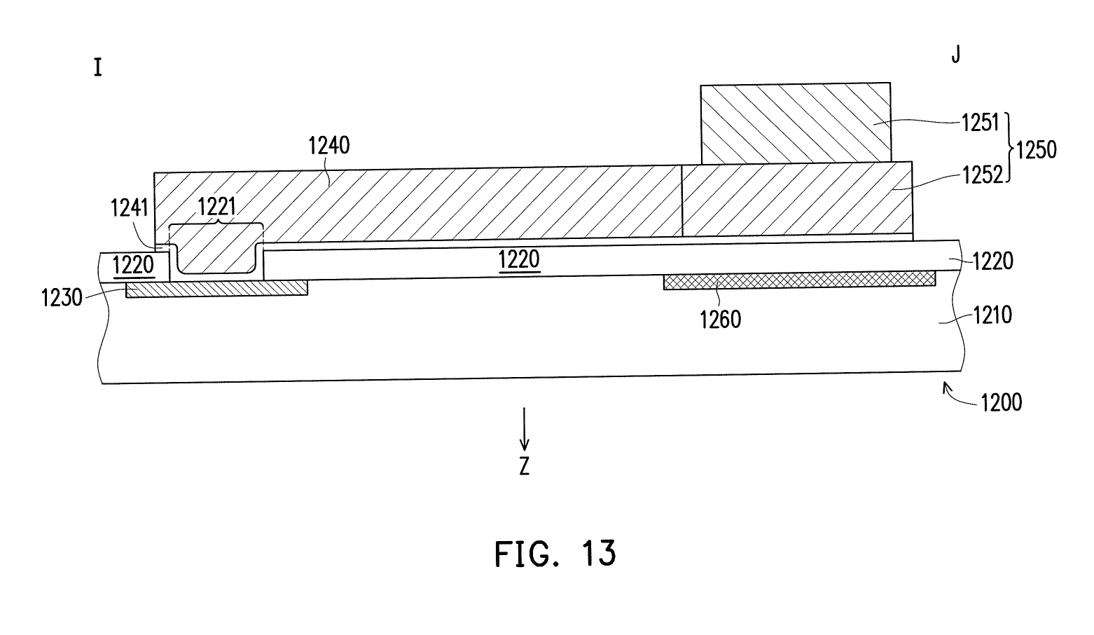

FIG. 12 is a schematic top view illustrating a layout structure of an integrated circuit 1200 according to another embodiment of the invention. FIG. 13 is a schematic cross-sectional view illustrating the integrated circuit 1200 depicted in FIG. 12 along sectional line I-J according to an embodiment of the invention. Referring to FIG. 12 and FIG. 13, the integrated circuit 1200 includes a chip 1210, a passivation layer 1220, a first metal internal connection 1230, a routing wire 1240, an adhesive layer 1241, a bonding area 1250 and a first metal pad 1260. The bonding area 1250 includes a metal bump 1251 and a routing layer 1252. The chip 1210, the passivation layer 1220, the first metal internal connection 1230, the routing wire 1240, the adhesive layer 1241, the bonding area 1250, the metal bump 1251, the routing layer 1252 and the first metal pad 1260 as illustrated in FIG. 12 and FIG. 13 may refer to related descriptions for the chip 210, the passivation layer 220, the first metal internal connection 230, the routing wire 240, the adhesive layer 241, the bonding area 250, the metal bump 251, the routing layer 252 and the first metal pad 260 as illustrated in FIG. 1, FIG. 2, FIG. 3A to FIG. 3C and FIG. 4A to FIG. 4C, which are not repeated hereinafter.

In the embodiment shown by FIG. 12 and FIG. 13 (but not limited thereto), the passivation layer has a first opening 1221. The first opening 1221 as illustrated in FIG. 12 may refer to related descriptions for the first opening 221 as illustrated in FIG. 1, FIG. 2, FIG. 3A to FIG. 3C and FIG. 4A to FIG. 4C. A first end of the routing wire 1240 electrically connects to a first end of the first metal internal connection 1230 through the first opening 1221 of the passivation layer 1220 by the adhesive layer 1241.

No opening is provided on the passivation layer 1220 between the routing layer 1252 and the first metal pad 1260. The first metal pad 1260 is disposed under the passivation layer 1220. The bonding area 1250 is located above the first metal pad 1260 in a vertical direction of the chip 1210. The routing layer 1252 of the bonding area 1250 is disposed on the passivation layer 1220, and the routing layer 1252 electrically connects to the routing wire 1240. The metal bump 1251 is disposed on the passivation layer 1220, and disposed on the routing layer 1252. The metal bump 1251 may serve as a dummy bump for balancing a bonding torque ratio and solving an IC Warpage phenomenon while bonding. The IC Warpage phenomenon may become even more obvious when thinning the integrated circuit (e.g., a thickness of the integrated circuit ≦200 μm).

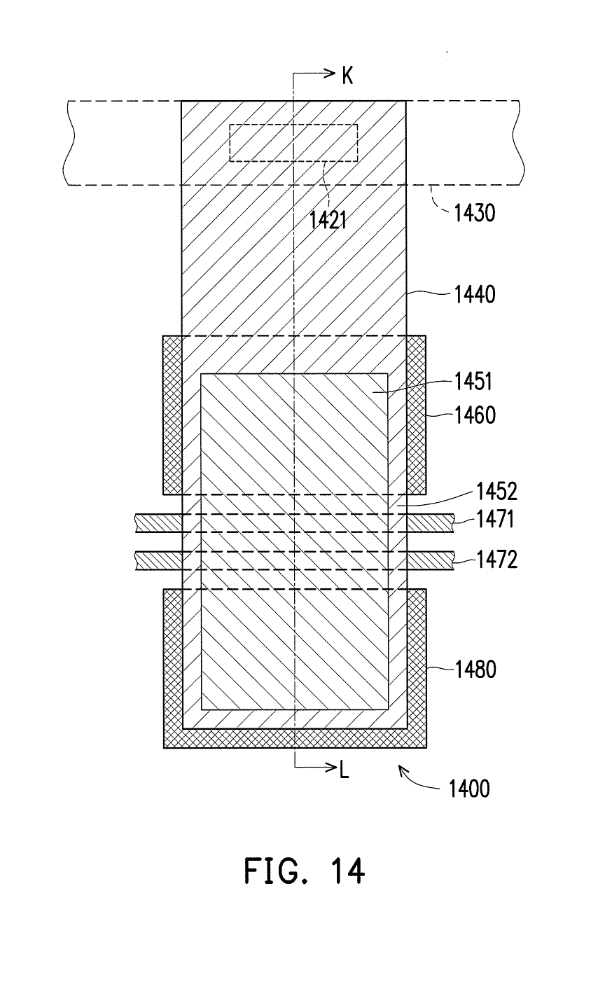

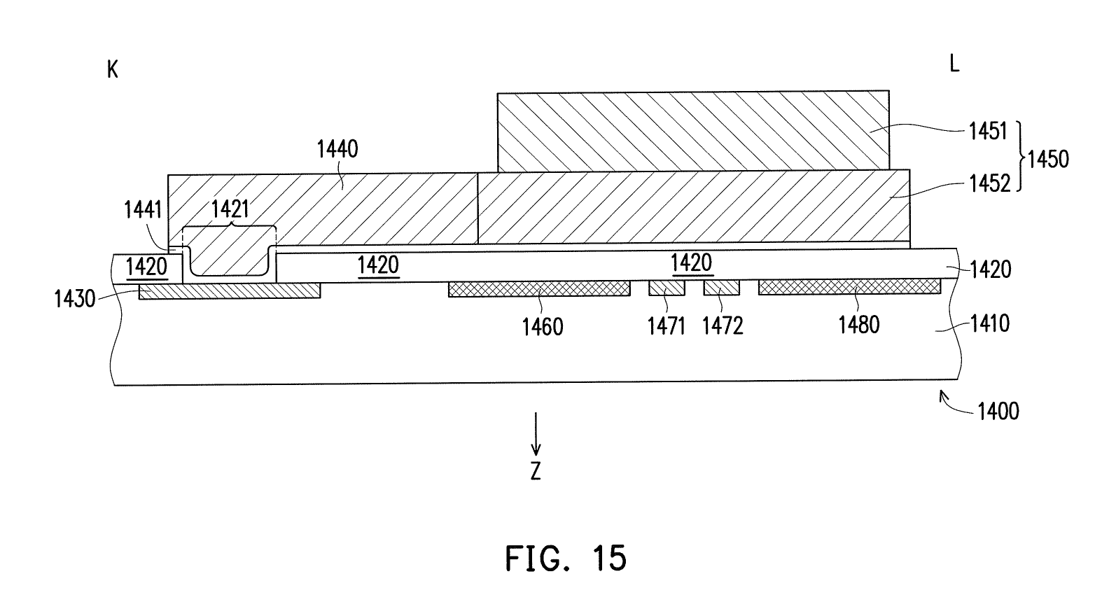

FIG. 14 is a schematic top view illustrating a layout structure of an integrated circuit 1400 according to yet another embodiment of the invention. FIG. 15 is a schematic cross-sectional view illustrating the integrated circuit 1400 depicted in FIG. 14 along sectional line K-L according to an embodiment of the invention. Referring to FIG. 14 and FIG. 15, the integrated circuit 1400 includes a chip 1410, a passivation layer 1420, a first metal internal connection 1430, a routing wire 1440, an adhesive layer 1441, a bonding area 1450, a first metal pad 1460, a second metal pad 1480, a metal internal connection 1471 and a metal internal connection 1472. The bonding area 1450 includes a metal bump 1451 and a routing layer 1452. The chip 1410, the passivation layer 1420, the first metal internal connection 1430, the routing wire 1440, the adhesive layer 1441, the bonding area 1450, the metal bump 1451, the routing layer 1452 and the first metal pad 1460 as illustrated in FIG. 14 and FIG. 15 may refer to related descriptions for the chip 1210, the passivation layer 1220, the first metal internal connection 1230, the routing wire 1240, the adhesive layer 1241, the bonding area 1250, the metal bump 1251, the routing layer 1252 and the first metal pad 1260 as illustrated in FIG. 12 and FIG. 13, which are not repeated hereinafter.

In the embodiment shown by FIG. 14 and FIG. 15 (but not limited thereto), the passivation layer has a first opening 1421. The first opening 1421 as illustrated in FIG. 14 may refer to related descriptions for the first opening 221 as illustrated in FIG. 1, FIG. 2, FIG. 3A to FIG. 3C and FIG. 4A to FIG. 4C. A first end of the routing wire 1440 electrically connects to a first end of the first metal internal connection 1430 through the first opening 1421 of the passivation layer 1420 by the adhesive layer 1441.

In the embodiment shown by FIG. 14 and FIG. 15, the integrated circuit 1400 further includes the second metal pad 1480, the metal internal connection 1471 and the metal internal connection 1472. The second metal internal connections 1471 and 1472 may be a power line, a ground line, a data line, a control line, a floating metal or other wires in the chip 1410. The second metal internal connections 1471 and 1472 are disposed under the passivation layer 1420 and disposed in the chip 1410. The metal internal connections 1471 and 1472 as illustrated in FIG. 14 may refer to related descriptions for the metal internal connections 571 and 572 as illustrated in FIG. 5 and FIG. 6.

The first metal pad 1460 and the second metal pad 1480 are disposed under the passivation layer 1420. No opening is provided on the passivation layer 1420 between the routing layer 1452 and the first metal pad 1460. No opening is provided on the passivation layer 1420 between the routing layer 1452 and the second metal pad 1480. The routing layer 1452 of the bonding area 1450 is disposed on the passivation layer 1420, and the routing layer 1452 electrically connects to the routing wire 1440. The routing layer 1452 is located above the first metal pad 1460 and the second metal pad 1480 in a vertical direction of the chip 1410. The metal bump 1451 of the bonding area 1450 is disposed on the routing slayer 1452. Because no opening is provided on the passivation layer 1420 under the metal bump 1451, the metal internal connections 1471 and 1472 may be placed under the metal bump 1451, so as to increase a routing area of the top metal layer of the chip 1410 in order to facilitate the metal internal connections in routing design.

Although the present disclosure has been described with reference to the above embodiments, it will be apparent to one of ordinary skill in the art that modifications to the described embodiments may be made without departing from the spirit of the disclosure. Accordingly, the scope of the disclosure will be defined by the attached claims and not by the above detailed descriptions.

What is claimed is:

1. An integrated circuit, comprising:
a chip;
a passivation layer, disposed on the chip, wherein the passivation layer has a first opening;
a first metal internal connection, disposed under the passivation layer and disposed in the chip;
a routing wire, disposed on the passivation layer, wherein a first end of the routing wire electrically connects to a first end of the first metal internal connection through the first opening of the passivation layer; and
a bonding area, disposed on the passivation layer, wherein the bonding area electrically connects to a second end of the routing wire.

2. The integrated circuit of claim 1, wherein the routing wire and the bonding area are disposed above the passivation layer.

3. The integrated circuit of claim 1, wherein the first metal internal connection belongs to a top metal layer of the chip.

4. The integrated circuit of claim 1, wherein a material of the routing wire comprises Au, an Au compound, an Au alloy, Cu, a Cu compound, a Cu alloy, Ni, a Ni compound, a Ni alloy, Pd, a Pd compound or a Pd alloy.

5. The integrated circuit of claim 1, wherein the passivation layer further has a second opening, and the integrated circuit further comprises:
a first metal pad, disposed under the passivation layer and at least partially located under the second opening;
wherein the bonding area electrically connects to the first metal pad through the second opening of the passivation layer.

6. The integrated circuit of claim 5, wherein a material of the first metal pad comprises Al, an Al compound, an Al alloy, Cu, a Cu compound or a Cu alloy.

7. The integrated circuit of claim 5, wherein a short edge length of the second opening is 4 μm to 80 μm.

8. The integrated circuit of claim 5, wherein the short edge length of the second opening is 2 μm to 70 μn.

9. The integrated circuit of claim 5, wherein the bonding area comprises:
an adhesive layer, at least partially disposed in the second opening; and
a routing layer, disposed on the passivation layer, and electrically connecting to the routing wire, wherein the routing layer is disposed on the adhesive layer, and the routing layer electrically connects to the first metal pad through the second opening by the adhesive layer.

10. The integrated circuit of claim 9, wherein a material of the adhesive layer comprises Ti, a Ti compound or a TiW alloy, and a material of the routing layer comprises Au, an Au compound, an Au alloy, Cu, a Cu compound, a Cu alloy, Ni, a Ni compound, a Ni alloy, Pd, a Pd compound or a Pd alloy.

11. The integrated circuit of claim 9, wherein a height of the routing layer is 0.1 μm to 9 μm.

12. The integrated circuit of claim 11, wherein the height of the routing layer is 2 μm to 5 μm.

13. The integrated circuit of claim 9, wherein the bonding area further comprises:
a metal bump, disposed on the passivation layer, and disposed on the routing layer, wherein the metal bump electrically connects to the first metal pad through the second opening by the routing layer and the adhesive layer.

14. The integrated circuit of claim 13, wherein a height of the metal bump is 3 μm to 18 μm.

15. The integrated circuit of claim 14, wherein the height of the metal bump is 5 μm to 15 μm.

16. The integrated circuit of claim 13, wherein a height difference between the metal bump and the routing layer is greater than 5 μm.

17. The integrated circuit of claim 13, wherein a surface roughness of the metal bump is 0.05 μm to 2 μm.

18. The integrated circuit of claim 17, wherein the surface roughness of the metal bump is 0.8 μm to 1.7 μm.

19. The integrated circuit of claim 13, wherein a hardness of the metal bump is 25 to 120 Hv.

20. The integrated circuit of claim 19, wherein the hardness of the metal bump is 50 to 110 Hv.

21. The integrated circuit of claim 13, wherein a material of the metal bump comprises Au, an Au compound, an Au alloy, Cu, a Cu compound, a Cu alloy, Ni, a Ni compound, a Ni alloy, Pd, a Pd compound or a Pd alloy.

22. The integrated circuit of claim 13, wherein an area ratio of the second opening to the metal bump is 0% to 90% in a vertical direction of the chip.

23. The integrated circuit of claim 22, wherein the area ratio of the second opening to the metal bump is 5% to 33%.

24. The integrated circuit of claim 13, further comprising:
a second metal internal connection, disposed under the passivation layer and disposed in the chip, wherein the second metal internal connection is located at a first side of the first metal pad without contacting the first metal pad;
wherein the metal bump is at least partially overlapped with the first metal pad and at least partially overlapped with the second metal internal connection in a vertical direction of the chip.

25. The integrated circuit of claim 24, further comprising:
a second metal pad, disposed under the passivation layer and located at the first side of the first metal pad;
wherein the second metal internal connection is disposed between the first metal pad and the second metal pad; and the metal bump is at least partially overlapped with the second metal pad in the vertical direction of the chip.

26. The integrated circuit of claim 25, wherein the passivation layer further has a third opening, the second metal pad is at least partially located under the third opening, and the metal bump electrically connects to the second metal pad through the third opening of the passivation layer.

27. The integrated circuit of claim 1, wherein a height of the routing wire is 0.1 μm to 9 μm.

28. The integrated circuit of claim 27, wherein the height of the routing wire is 2 μm to 5 μm.

29. The integrated circuit of claim 1, further comprising:
a first metal pad, disposed under the passivation layer;
wherein the bonding area is located above the first metal pad in a vertical direction of the chip.

30. The integrated circuit of claim 29, wherein the bonding area comprises:
a routing layer, disposed on the passivation layer, and electrically connects to the routing wire.

31. The integrated circuit of claim 30, wherein the bonding area further comprises:
a metal bump, disposed on the passivation layer, and disposed on the routing layer.
